(19) United States
(12) Patent Application Publication
(10) Pub. No.: US 2024/0235176 A1
(43) Pub. Date: Jul. 11, 2024

(54) BREAKER OF DISCONTINUOUS JUMP CURRENT INDUCED BY INSULATOR-METAL TRANSITION IN AC POWER SYSTEM

(71) Applicant: Electronics and Telecommunications Research Institute, Daejeon (KR)

(72) Inventors: Hyun-Tak KIM, Daejeon (KR); Tae Moon ROH, Daejeon (KR)

(73) Assignee: Electronics and Telecommunications Research Institute, Daejeon (KR)

(21) Appl. No.: 18/563,243

(22) PCT Filed: Nov. 8, 2022
(86) PCT No.: PCT/KR2022/017433

§ 371 Date: Nov. 21, 2023

(30) Foreign Application Priority Data
Nov. 10, 2021 (KR) 10-2021-0154171

(51) Int. Cl. H02H 3/08

(52) U.S. Cl. CPC H02H 3/08

(57) ABSTRACT

Disclosed is a discontinuous jump current breaker, in an AC power system having an insulating material that exhibits nonlinear electrical characteristics between two electrodes, which blocks an AC power by observing a discontinuous jump current in which an insulator-metal transition occurs. The discontinuous jump current breaker includes a setting unit that sets the magnitude of a discontinuous jump current, a sensor unit including a metallic wire (Republic of Korea Patent Registration No. 10-1981640) parallel to an AC power wire, located at a separation distance d≥0, and that measures electromagnetic waves of an AC power, an amplifier unit that amplifies an analog signal of the metal wire, an analog-to-digital converter that converts the amplified analog signal to digital, a microcontroller unit including a memory unit for storing a program that drives the system, and a power blocking unit that blocks the discontinuous jump current.

### TECHNICAL FIELD

The present disclosure relates to a circuit breaker, and more particularly, relates to a discontinuous jump current breaker (DJCB) that blocks a discontinuous jump current generated when a transition occurs from an insulating material such as cuprous oxide (CuO₂) or hydrocarbon that exhibits electrically nonlinear characteristics and is formed due to oxidation of metals in power terminals or wires to a metal exhibiting electrically linear characteristics.

### BACKGROUND ART

Electrical fires do not happen when wires are inserted or connected in old outlets or old wires, but occurs a state in which wires are inserted or are connected. The characteristics of old outlets or old wires are that contact terminals of the wires are oxidized black, and black cuprous oxide (CuO₂), which is an insulating material that exhibits electrically nonlinear characteristics on its surface, is formed around a connection part of the outlet or a copper wire. In this case, an Insulator-to-Metal Transition (IMT) phenomenon (FIGS. 1, 100, and 200) occurs in the cuprous oxide, and a current may flow in a discontinuous jump 200. It is difficult to see this phenomenon in wires or outlets without the cuprous oxide.

Here, the academic study on the IMT phenomenon is illustrated in FIG. 1 (Non-Patent Document 2). FIG. 1 illustrates a measurement of an IMT jump by inputting a triangular wave to an IMT device 30 that is formed by a vanadium oxide (VO₂) insulating material in which the IMT phenomenon occurs, such as the cuprous oxide, and metal electrodes connected to both ends of the insulating material.

In addition, when the wire is half-short-circuited, the cross-sectional area through which the current flows in a half-short-circuited portion becomes smaller, resulting in higher resistance and heat concentration in that portion, whereby the cuprous oxide is easily formed. Pure cuprous oxide is an insulator with an energy gap, but in the absence of oxygen, CuO₂ becomes a semiconductor device with electrically nonlinear characteristics. When vinyl-based cables melt, hydrocarbons, which are organic semiconductors with semiconductor characteristics, are sometimes formed. The cuprous oxide formed on a wire sheath is characterized by exhibiting semiconductor characteristics, so a slight current flows. So, because of this slight current, before the IMT of the discontinuous jump occurs, the behavior of the current called a shoulder 100 as a semiconductor current appears (prior papers 1 and 2). When this current is flowing, it is difficult to observe the semiconductor current corresponding to the shoulder. After the jump after the shoulder, when a large current of linear metal characteristics continues for some time, Joule heat is generated due to the large current, and a fire is ignited by the heat. Therefore, when the power is blocked before heat is generated with a large current, fires may be prevented. Therefore, there is a need for a circuit breaker that detects the discontinuous jump of the current of the IMT phenomenon and controls the current. This is called an Insulator-Metal-Transition (or IMT) discontinuous jump current breaker. It is called a discontinuous jump current breaker for short.

Also, the occurrence of an IMT discontinuous current does not necessarily result in a fire. For example, when a motor is driven, such as in a household vacuum cleaner, the current jump may occur. Although these current jumps are fire-related, they may be necessary in some cases. Therefore, this jump current needs to be controlled and conveniently used to suit the situation.

Patent documents and non-patent documents described below are conventional art documents of the present disclosure.
(Patent Document 1) U.S. Pat. No. 6,339,525 B1 (Title: Arc fault detector with circuit interrupter).
(Patent Document 2) U.S. Pat. No. 6,532,139 B2 (Title: Arc fault circuit interrupter and circuit breaker having the same).
(Patent Document 3) Registered Patent No. KR 10-1981640 (Title: Current sensor for measuring alternating electromagnetic waves and circuit breaker using the same), Family Patent: Pub. No.: US 2020/0182913 A1, Current sensor for measuring alternating electromagnetic wave and a current breaker using the same.
(Non-Patent Document 1) H. T. Kim et al., “Mechanism and observation of Mott transition in VO2-based two- and three-terminal devices”, New Journal of Physics 6, 52 (2004).
(Non-Patent Document 2) B. J. Kim et al., ‘Temperature dependence of the first-order metal-insulator transition in VO2 and programmable critical temperature sensor’, Applied Physics Letters 90, 023515 (2007).

### DETAILED DESCRIPTION OF THE INVENTION

### Technical Problem

The problem to be solved by the present disclosure is to make a circuit breaker that detects the magnitude of a discontinuous current jump generated as an insulator-to-metal transition (IMT) occurs from a black rust and blocks power by generating a control signal for power blocking according to the magnitude of the discontinuous current jump, in a terminal of an outlet with the black rust, for example cuprous oxide (CuO₂), or a power wire including a plug power terminal (same as having an IMT device, FIG. 1(c), and FIG. 1(d)) plugged into the outlet of a power device with the black rust, in AC power system.

### Technical Solution

To achieve the above object, the present disclosure measures a current jump that occurs when an insulator-to-metal transition occurs, and blocks power supplied to an AC power system when the magnitude of a jump current exceeds a certain threshold in the AC power system (FIGS. 1(c) and 1(d)) including a power source for a power device connected to an outlet having an insulating material that exhibits electrically nonlinear characteristics between two electrodes.

An IMT jump current breaker has a configuration including a sensor unit 310 including a hyun-tak line sensor (Patent Document 3) that measures a current by placing a metal wire parallel to an AC power wire 313 in which an insulator-metal transition occurs, an amplifying unit 320 that amplifies a current signal obtained from the sensor unit with an operational amplifier, an analog-to-digital converter (ADC) unit 340 that converts the amplified analog signal into digital, a threshold current setting unit 370 that sets a magnitude of the threshold jump current, a microcontroller 390 including a memory unit for storing a program that determines an threshold jump current by comparing a magnitude of a read threshold current jump with a measured and digitized current signal and generates a signal for power control, and a power control unit 380 including a relay for power control or a power semiconductor device.

The analog-to-digital converter unit may be built into a microcontroller.

The distance ‘d’ between the power wire and the hyun-tak line sensor line in the sensor unit includes a range of d≥0.

The threshold current setting unit 370 for determining the threshold current includes a DIP switch 373 having a digital type and an analog switch 376.

When the threshold current setting unit is composed of an analog switch, the analog switch includes being connected to a separate analog-to-digital converter instead of a converter that converts a current signal into analog-to-digital (FIG. 3(b)).

For example, when setting the threshold current with the 2-digit DIP switch of FIG. 3(a), ‘00’ means that a certain quantized value is not set, ‘01’ means one times a certain quantized value, ‘10’ means two times a certain quantized value, ‘11’ means three times a certain quantized value. In this case, the quantized value may be set to the starting value of the current jump.

In the case of setting the threshold current with the analog switch of FIG. 3(b), it means that a certain quantized value becomes an analog multiple using the observed analog value. That is, the analog multiple means a multiple of the quantized value. For example, when setting the starting value of the current jump as a quantized value, the jump current value becomes a multiple of the current jump starting value.

As another example, a difference between a starting value I_{Jump-start} of the jump current and a measured value I_{Jump-start-1} just before the measurement of the jump current start value, in continuous measurements on the power wire, that is, when ΔI_{before jump}=I_{Jump-start}−I_{Jump-start-1}, the jump current, ΔIⱼᵤₘₚ, is an integer multiple of ΔI_{before jump} and includes ΔIⱼᵤₘₚ≥ΔI_{before jump}×m. Here, ‘m’ corresponds to the value set in an external switch.

For example, when I_{Jump-start-1}=10 A, I_{Jump-start}=20 A, I_{Jump}=100 A, then ΔI_{before jump}=20 A−10 A=10 A, and ΔIⱼᵤₘₚ=I_{Jump}−I_{Jump-start}=80 A. Here, the dip switch setting is set to m=3 as ‘11’. So, (ΔIⱼᵤₘₚ=80 A)≥(ΔI_{before jump}×m=10×(3=m)), and a control signal for power blocking is generated. Alternatively, the delta ratio (ΔR) may be considered. Since ΔR_{before jump}=ΔI_{before jump}/I_{Jump-start-1}=10 A/10 A=1, and ΔR_{Jump}=ΔI_{Jump}/I_{Jump-start}=80 A/20 A=4>(m=3), a power blocking signal is generated. In this case, only ΔR_{Jump} may be considered.

Accordingly, the magnitude of the threshold jump current includes determining a difference between two successive values previously measured as a certain quantized value, or setting a previously measured value as a certain quantized value and determining a multiple of that value.

The switching unit for blocking the jump current in the power control unit 380 is operated depending on a switch control signal 384 for power blocking generated by the MCU 350 to protect an AC power device 382.

The power blocking switch includes a relay 388 or a power semiconductor device 389 (FIG. 4). The relay and power semiconductor device are controlled by the control device 386 of the jump current blocking switches 388 and 389.

The control device 386 of the jump current blocking switches 388 and 389 includes a field effect transistor, a bipolar transistor, a thyristor (Silicon Controlled Rectifier: SCR), a triac, a photo transistor, a photo SCR, or a photo triac. The jump current blocking switch includes the relay 388 or the power semiconductor device 389.

The relay is an electromagnet, which means that the switch is operated by electrical power, and includes a solenoid that operates on the same principle as the relay.

The power semiconductor device 389 includes a field effect transistor for power or an inter gate bipolar transistor (IGBT).

The power unit 395 supplies power to an IMT jump current breaker 300 of the present disclosure. The power unit includes a battery prepared in case power is not supplied to the IMT jump current breaker when blocking the jump current.

### Advantageous Effects of the Invention

The insulator-metal transition jump current breaker using a hyun-tak line current sensor 316 according to the present disclosure has a great effect in preventing fire by measuring discontinuous current jump in the power system, and allows the use of power devices that does not cause fires, such as motors.

Other objects and advantages of the present disclosure in addition to the above objects and effects will become apparent through the detailed description of the embodiments with reference to the accompanying drawings.

### DESCRIPTION OF THE DRAWINGS

FIG. 1(a) illustrates an observation of a discontinuous jump current when an insulator transitions to a metal as an Insulator-Metal-Transition (IMT) or Metal-Insulator-Transition (MIT) occurs when triangular AC current is applied to the insulator having an insulating material that exhibits electrically nonlinear characteristics between two electrodes. The observation is cited in reference paper 1.

FIG. 1(b) is a conceptual diagram of an insulator-metal-transition device having an insulating material between two electrodes.

FIG. 1(c) illustrates that 51 (electrode)-52 (black rust)-54 (electrode) and 51 (electrode)-53 (black rust)-55 (electrode) are formed as IMT devices, and a location 50 where IMT occurs, when a plug is inserted into an outlet.

FIG. 1(d) illustrates that 56 (electrode)-58 (black rust)-61 (electrode) and 57 (electrode)-59 (black rust)-62 (electrode) are formed as IMT devices, and a location 50 where IMT occurs, when a plug is inserted into an outlet.

FIG. 2 illustrates an internal functional diagram of a discontinuous jump current breaker of the present disclosure.

FIG. 3(a) illustrates a connection of a dip switch for setting a threshold jump current.

FIG. 3(b) illustrates a connection of an analog switch for determining a threshold jump current.

FIG. 4(a) illustrates a functional diagram of a switching unit that blocks a discontinuous jump current using a relay.

FIG. 4(b) illustrates a functional diagram of a switching unit that blocks a discontinuous jump current using a power semiconductor device.

FIG. 5 illustrates an AC 110V single-phase discontinuous jump current breaker developed as an embodiment of the present disclosure and a wiring diagram of an embodiment.

FIG. 6 illustrates a discontinuous jump current waveform measured in a discontinuous jump current breaker of FIG. 5.

FIG. 7 illustrates a flowchart of a program to block a discontinuous jump current.

### BEST MODE

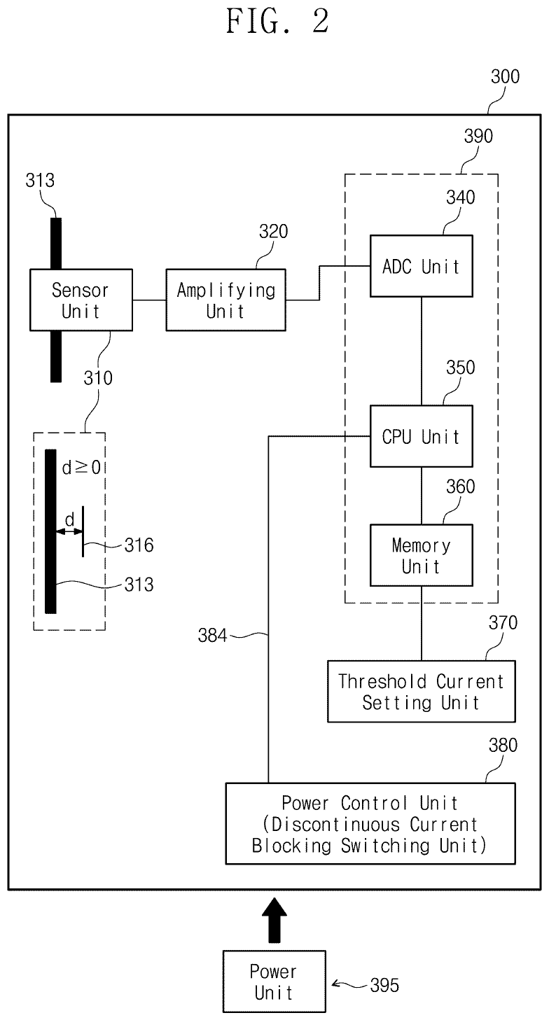

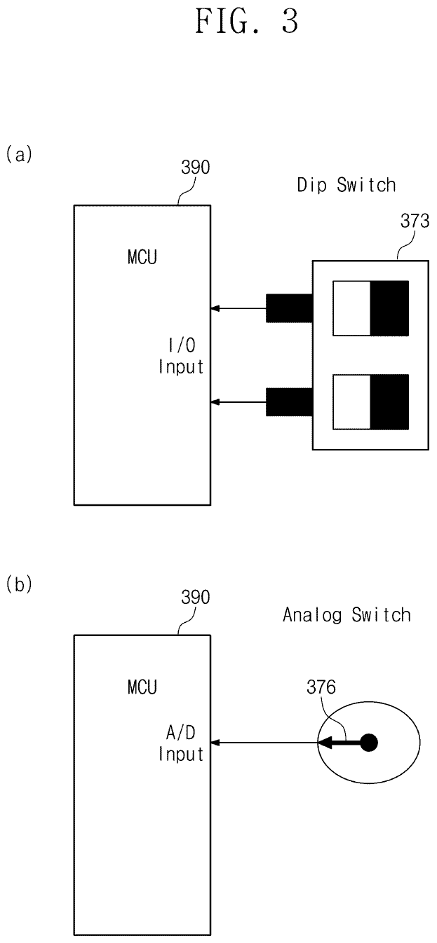

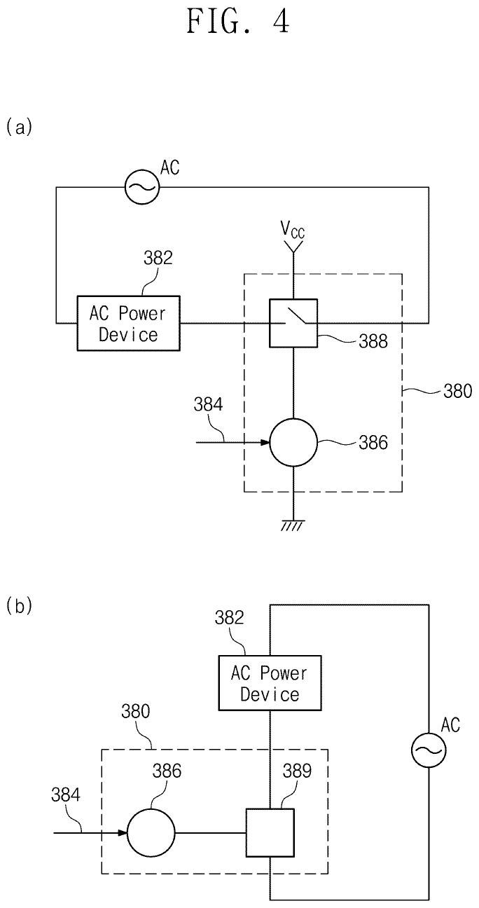

A drawing illustrating the best mode for implementing the present disclosure is FIG. 2.

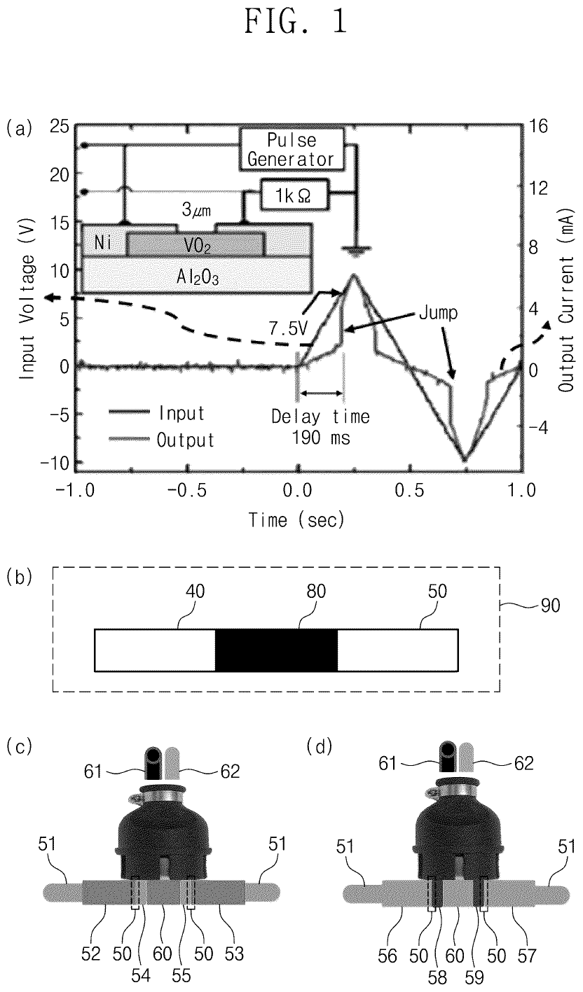

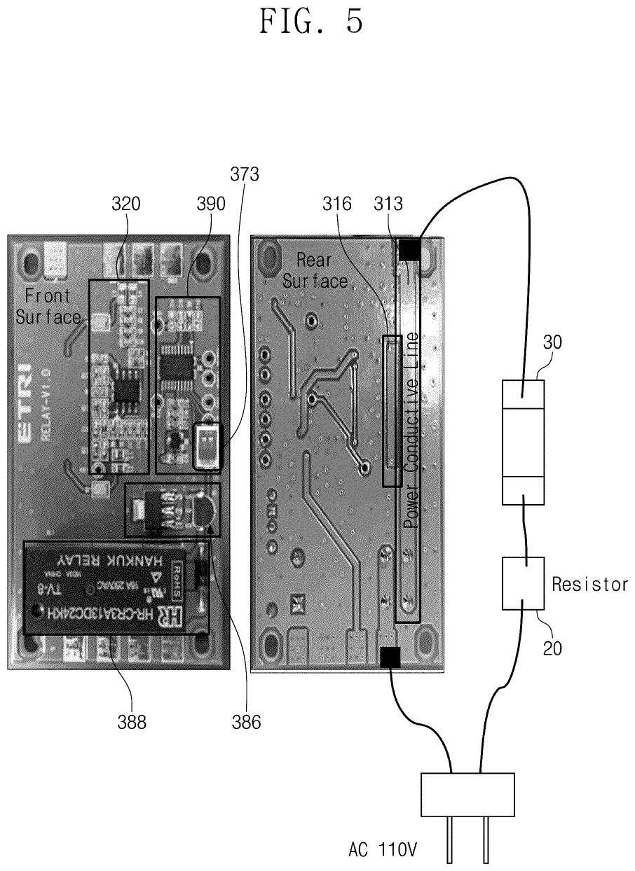

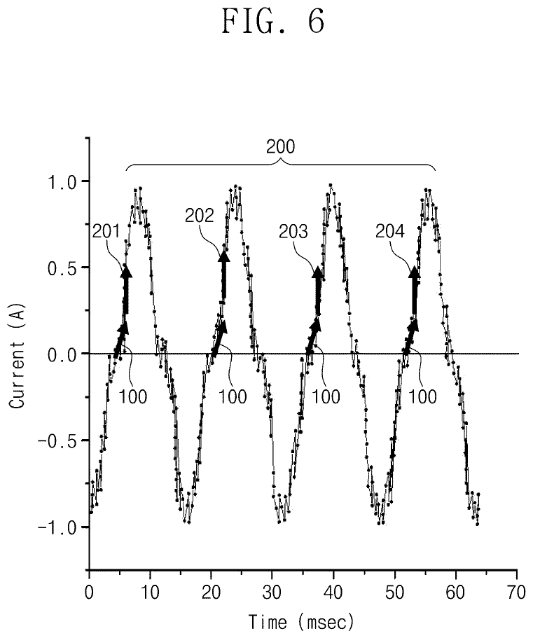

As an embodiment of the present disclosure, an IMT discontinuous jump current breaker of FIG. 5 is manufactured according to the functional diagram of the circuit breaker of FIG. 2. Vanadium dioxide (VO₂) is used as an insulating material of the IMT device 30 to easily implement the IMT discontinuous jump in a laboratory. In the absence of large current in the laboratory, the resistance of the IMT device after the IMT is set to about 1 KW. A pulse voltage of up to 1 A is allowed to flow after the IMT at an AC voltage of 110V. Experimental data measured by connecting the IMT device as shown in FIG. 5 and using the hyun-tak line current sensor 316 are illustrated in FIG. 6. This data illustrates the shoulder 100 and pulses (200: 201, 202, 203, and 204) after the jump like the data in FIG. 1(a). The data of those current jumps, Deltas A, are illustrated in Table 1. As an external switch to determine the magnitude of the jump, to implement function of the 2-bit DIP switch 373 with High-Low to an external I/O terminal of FIG. 5, signals ‘00’, ‘01’, ‘10’, and ‘11’ are provided.

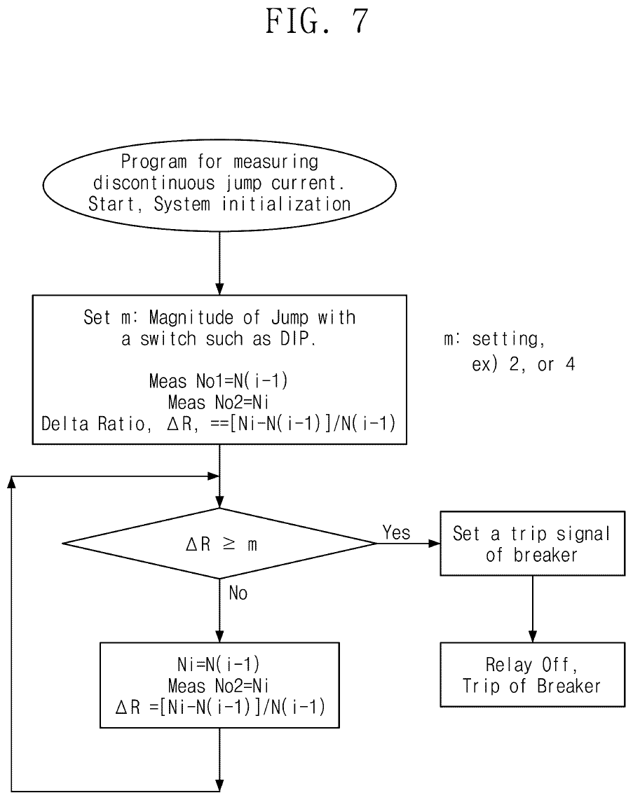

As an example, the dip switch setting ‘00’ corresponds to a setting value m=0, ‘01’ corresponds to m=1, ‘10’ corresponds to m=2, ‘11’ corresponds to m=3, in the flowchart of FIG. 7.

The Δ value of the current jump obtained from the data in Table 1 below corresponds to the setting value ‘m’ in the program flow chart of FIG. 7 as the setting value of the dip switch 373 (refer to FIG. 5). As ‘11’ of the dip switch, when m=3 is set and the Δ is 3 or more, the MCU 390 determines that the measured current is a current jump for power blocking and provides a power blocking signal to the relay 388, which is a jump current blocking switch. Therefore, with the system of FIG. 5, it is confirmed that the relay 388 blocks power under the above conditions.

TABLE 1
Jumps 1, 2, 3, and 4 are in FIG. 6, and a current jump width ratio is defined as ΔR = [Ni-
N(i-1)]/N(i-1) (FIG. 7). In data in Table 1, the jump width AR is rounded and taken as an
integer.

| | Jump 1( 201) | | | Jump 2 (202) | | | Jump 3 (203) | | | Jump 4 (204) | | |
|---|---|---|---|---|---|---|---|---|---|---|---|---|
| NO | Time | Current | ΔR | Time | Current | ΔR | Time | Current | ΔR | Time | Current | ΔR |
| N1 | 5.85 | 13 | | 20.9 | 13 | | 37.1 | 46 | | 53.43 | 188 | |
| N2 | 6.07 | 651 | 49 | 21.3 | 83 | 5 | 37.1 | 269 | 5 | 53.99 | 728 | 3 |
| N3 | 6.12 | 576 | 0 | 21.6 | 295 | 3 | 37.6 | 225 | 0 | 54.12 | 652 | 0 |
| N4 | 6.59 | 628 | 0 | | | | | | | 54.47 | 802 | 0 |

### INDUSTRIAL APPLICABILITY

The present disclosure relates to a discontinuous jump current breaker. In more detail, the present disclosure is applicable to a discontinuous jump current breaker (DJCB) that blocks a discontinuous jump current generated when a transition occurs from an insulating material such as cuprous oxide (CuO₂) or hydrocarbon that exhibits electrically nonlinear characteristics and is formed due to oxidation of metals in power terminals or wires to a metal exhibiting electrically linear characteristics.

1. A discontinuous jump current breaker comprising: a program that determines a discontinuous jump current and generates an AC power blocking signal by comparing a difference between the two current data continuously measured in a power wire with a magnitude of a discontinuous jump of a blocking current set on an outside of an input switch in the discontinuous jump current breaker, when an insulating material is converted into a metallic state that has linear electrical characteristics, in an AC power system including the power wire of an outlet to which a power source for a power device having the insulating material having nonlinear electrical characteristics is connected between two electrodes.

2. The discontinuous jump current breaker of claim 1, wherein the discontinuous jump current breaker includes:
a threshold current setting unit 370 configured to set the magnitude of the discontinuous jump current;
a sensor unit 310 including a metallic wire parallel to an AC power wire, of which separation distance from the AC power wire is greater than or equal to 0, and configured to measure electromagnetic waves of an AC power;
an amplifier unit 320 configured to amplify an analog signal of the metal wire;
an analog-to-digital converter 340 configured to convert the amplified analog signal to digital;
a microcontroller unit 390 including a memory unit 360 for storing the program for determining a threshold jump current and outputting a signal for a power control by comparing a magnitude of a read threshold jump current with a measured and digitized current signal; and
a power control unit 380 configured to break the discontinuous jump current.

3. The discontinuous jump current breaker of claim 1, wherein the threshold current setting unit includes:
a dip switch or an analog switch that sets a value corresponding to the magnitude of the discontinuous jump current.

4. The discontinuous jump current breaker of claim 2, wherein the power control unit includes:
a transistor or an SCR that is connected to the AC power blocking signal and controls an electromagnet relay for a power blocking.

5. The discontinuous jump current breaker of claim 4, wherein the electromagnet relay for the power blocking includes:
a solenoid switch or a trip coil that switches contacts by an electromagnetic force flowing through a coil.

6. The discontinuous jump current breaker of claim 2, wherein the power control unit includes:
a transistor, a phototransistor, or an SCR that is connected to the AC power blocking signal and controls a power device for a power blocking.

7. The discontinuous jump current breaker of claim 6, wherein the power device for the power blocking includes:
an inter gate bipolar transistor (IGBT), a triodo for alternating current (TRIAC), or an SCR for a power.
